(19) United States
(12) Patent Application Publication
(10) Pub. No.: US 2026/0190512 A1
(43) Pub. Date: Jul. 2, 2026

(54) Multi-Bandgap Charge-Coupled Device (CCD)

(71) Applicant: The Board of Regents of the University of Oklahoma, Norman, OK (US)

(72) Inventors: Ian Sellers, Norman, OK (US); Xinyu Dai, Norman, OK (US); Vincent R. Whiteside, Buffalo, NY (US); Nathaniel Edison Lydick, Ann Arbor, MI (US); Brett Bonine, Norman, OK (US)

(21) Appl. No.: 19/542,114

(22) Filed: Feb. 17, 2026

Related U.S. Application Data
(63) Continuation-in-part of application No. 17/684,202, filed on Mar. 1, 2022.
(60) Provisional application No. 63/159,767, filed on Mar. 11, 2021.

(51) Int. Cl. H10F 39/15; H10F 39/00; H10F 77/124

(52) U.S. Cl. CPC H10F 39/156; H10F 39/157; H10F 39/805; H10F 39/806; H10F 77/1248

(57) ABSTRACT

A CCD comprises: a primary device configured to capture visible light and comprising: a first layer comprising a first semiconductor material; and a second layer comprising a second semiconductor material; and a secondary device configured to capture near-IR light and comprising: a third layer comprising a third semiconductor material and positioned such that the second layer is between the first layer and the third layer; and a fourth layer comprising a fourth semiconductor material and positioned such that the third layer is between the second layer and the fourth layer.

### CROSS-REFERENCE TO RELATED APPLICATIONS

The present application is a continuation-in-part application which claims priority to U.S. patent app. Ser. No. 17/684,202, filed on Mar. 1, 2022, which claims priority to U.S. Prov. Patent App. No. 63/159,767, filed on Mar. 11, 2021, both of which are hereby expressly incorporated herein by reference in their entireties.

### BACKGROUND

Modern astronomical observations are capable of producing images of nebulae, galaxies, star clusters, and other objects, and they perform spectral analyses over a broad energy spectrum by utilizing a CCD for detection. To characterize a particular object, many astronomical observations consist of repetitive viewings with several different filters to span the spectrum of interest, which is a very time-consuming process. However, this is not an efficient way to gather the spectral information.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 is a schematic diagram of CCD.

FIG. 2 is a schematic diagram of a CCD sensor.

FIG. 3 is a graph of sensitivity, efficiency, or light intensity absorbed as a function of wavelength for the CCD device in FIG. 1. The areas under the absorption curves are used to calculate the wavelength selectivities for particular absorption layers.

FIG. 4 is a flowchart illustrating a method of performing an image observation.

### DETAILED DESCRIPTION

Disclosed herein are embodiments for a multi-bandgap CCD. The embodiments provide for a design for a sensor that simultaneously images multiple light bands to function as a sensor or camera for astronomical, surveilling, professional, and other types of imaging. This design will achieve a similar image quality to those produced by traditional CCD cameras (in terms of resolution, sensitivity, noise, etc.), while reducing the need for repeated observations with different filters by utilizing the inherit properties of semiconductors, therefore reducing the overall exposure time by the number of filters that would have previously been needed. In other words, instead of taking a separate exposure for each wavelength band, the CCD takes a single exposure for a combination of wavelength bands. The multi-bandgap CCD is more sensitive and less noisy than most CMOS sensors, and the multi-bandgap CCD has higher-quality ADC components and better pixel-to-pixel reproducibility of images because every pixel is read out through the same amplifier rather than a separate amplifier per pixel like with CMOS sensors. For those reasons, the multi-bandgap CCD is more mature for astronomy imaging. In addition, the layout of the multi-bandgap CCD can have all of the electronics except for some gate electrodes off to one side of the imaging area of the chip, making it more appropriate than CMOS sensors for the stacked-layer design. It is advantageous to reduce the absorption overlaps between adjacent layers, such that the signal from a light source in a wavelength range is selectively absorbed by one layer, enabling the source emission at different wavelength ranges to be distinguished.

It should be understood at the outset that, although an illustrative implementation of one or more embodiments are provided below, the disclosed systems and/or methods may be implemented using any number of techniques, whether currently known or in existence. The disclosure should in no way be limited to the illustrative implementations, drawings, and techniques illustrated below, including the exemplary designs and implementations illustrated and described herein, but may be modified within the scope of the appended claims along with their full scope of equivalents.

Before describing various embodiments of the present disclosure in more detail by way of exemplary description, examples, and results, it is to be understood that the present disclosure is not limited in application to the details of methods and compositions as set forth in the following description. The present disclosure is capable of other embodiments or of being practiced or carried out in various ways. As such, the language used herein is intended to be given the broadest possible scope and meaning; and the embodiments are meant to be exemplary, not exhaustive. Also, it is to be understood that the phraseology and terminology employed herein is for the purpose of description and should not be regarded as limiting unless otherwise indicated as so. Moreover, in the following detailed description, numerous specific details are set forth in order to provide a more thorough understanding of the disclosure. However, it will be apparent to a person having ordinary skill in the art that the embodiments of the present disclosure may be practiced without these specific details. In other instances, features which are well known to persons of ordinary skill in the art have not been described in detail to avoid unnecessary complication of the description.

Unless otherwise defined herein, scientific and technical terms used in connection with the present disclosure shall have the meanings that are commonly understood by those having ordinary skill in the art. Further, unless otherwise required by context, singular terms shall include pluralities and plural terms shall include the singular.

All patents, published patent applications, and non-patent publications mentioned in the specification are indicative of the level of skill of those skilled in the art to which the present disclosure pertains. All patents, published patent applications, and non-patent publications referenced in any portion of this application are herein expressly incorporated by reference in their entirety to the same extent as if each individual patent or publication was specifically and individually indicated to be incorporated by reference.

As utilized in accordance with the methods and compositions of the present disclosure, the following terms, unless otherwise indicated, shall be understood to have the following meanings:

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or when the alternatives are mutually exclusive, although the disclosure supports a definition that refers to only alternatives and “and/or.” The use of the term “at least one” will be understood to include one as well as any quantity more than one, including but not limited to, 2, 3, 4, 5, 6, 7, 8, 9, 10, 15, 20, 30, 40, 50, 100, or any integer inclusive therein. The term “at least one” may extend up to 100 or 1000 or more, depending on the term to which it is attached; in addition, the quantities of 100/1000 are not to be considered limiting, as higher limits may also produce satisfactory results. In addition, the use of the term “at least one of X, Y and Z” will be understood to include X alone, Y alone, and Z alone, as well as any combination of X, Y and Z.

As used herein, all numerical values or ranges include fractions of the values and integers within such ranges and fractions of the integers within such ranges unless the context clearly indicates otherwise. Thus, to illustrate, reference to a numerical range, such as 1-10 includes 1, 2, 3, 4, 5, 6, 7, 8, 9, 10, as well as 1.1, 1.2, 1.3, 1.4, 1.5, etc., and so forth. Reference to a range of 1-50 therefore includes 1, 2, 3, 4, 5, 6, 7, 8, 9, 10, 11, 12, 13, 14, 15, 16, 17, 18, 19, 20, etc., up to and including 50, as well as 1.1, 1.2, 1.3, 1.4, 1.5, etc., 2.1, 2.2, 2.3, 2.4, 2.5, etc., and so forth. Reference to a series of ranges includes ranges which combine the values of the boundaries of different ranges within the series. Thus, to illustrate reference to a series of ranges, for example, of 1-10, 10-20, 20-30, 30-40, 40-50, 50-60, 60-75, 75-100, 100-150, 150-200, 200-250, 250-300, 300-400, 400-500, 500-750, 750-1,000, includes ranges of 1-20, 10-50, 50-100, 100-500, and 500-1,000, for example. A reference to degrees such as 1 to 90 is intended to explicitly include all degrees in the range.

As used herein, the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AAB, BBC, AAABCCCC, CBBAAA, CABABB, and so forth. The skilled artisan will understand that typically there is no limit on the number of items or terms in any combination, unless otherwise apparent from the context.

Throughout this application, the terms “about” and “approximately” are used to indicate that a value includes the inherent variation of error. Further, in this detailed description, each numerical value (e.g., temperature or time) should be read once as modified by the term “about” (unless already expressly so modified), and then read again as not so modified unless otherwise indicated in context. As noted, any range listed or described herein is intended to include, implicitly or explicitly, any number within the range, particularly all integers, including the end points, and is to be considered as having been so stated. For example, “a range from 1 to 10” is to be read as indicating each possible number, particularly integers, along the continuum between about 1 and about 10. Thus, even if specific data points within the range, or even no data points within the range, are explicitly identified or specifically referred to, it is to be understood that any data points within the range are to be considered to have been specified, and that the inventors possessed knowledge of the entire range and the points within the range. The use of the term “about” may mean a range including ±10% of the subsequent number unless otherwise stated.

As used herein, the term “substantially” means that the subsequently described parameter, event, or circumstance completely occurs or that the subsequently described parameter, event, or circumstance occurs to a great extent or degree. For example, the term “substantially” means that the subsequently described parameter, event, or circumstance occurs at least 90% of the time, or at least 91%, or at least 92%, or at least 93%, or at least 94%, or at least 95%, or at least 96%, or at least 97%, or at least 98%, or at least 99%, of the time, or means that the dimension or measurement is within at least 90%, or at least 91%, or at least 92%, or at least 93%, or at least 94%, or at least 95%, or at least 96%, or at least 97%, or at least 98%, or at least 99%, of the referenced dimension or measurement (e.g., length).

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

As used herein, the term “sensitivity” is defined as the efficiency of an absorption layer as a function of wavelength.

As used herein, the term “selectivity” is defined as the concentration of the readout signal from one layer in a wavelength range and is defined as the area under a sensitivity curve for the dominating layer in a wavelength range over the area of the sensitivity curves from adjacent layers in the same wavelength range.

As used herein any reference to “we” as a pronoun herein refers generally to laboratory personnel or other contributors who assisted in the laboratory procedures and data collection and is not intended to represent an inventorship role by said laboratory personnel or other contributors in any subject matter disclosed herein.

The following abbreviations apply:
ADC: analog-to-digital converter
AR: anti-reflective
B: light spectrum with midpoint of 445 nm (blue)
CCD: charge-coupled device
CeF₃: cerium fluoride
CMOS: complementary metal-oxide-semiconductor
coat: coating
DBR: distributed Bragg reflector
GaAs: gallium arsenide
GaP: gallium phosphide
GaSb: gallium antimonide
GRIN: gradient-index
H: light spectrum with midpoint of 1,630 nm
I: light spectrum with midpoint of 806 nm (infrared)
InAs: indium arsenide
InGaAsP: indium gallium arsenide phosphide
InGaP: indium gallium phosphide
InP: indium phosphide
IR: infrared
J: light spectrum with midpoint of 1,220 nm
MgF₂: magnesium fluoride
nm: nanometer(s)
R: light spectrum with midpoint of 658 nm (red)
SiO₂: silicon dioxide
U: light spectrum with midpoint of 365 nm (UV)
UV: ultraviolet
V: light spectrum with midpoint of 551 nm (visual)
Y: light spectrum with midpoint of 1,020 nm
Z: light spectrum with midpoint of 900 nm.

For semiconducting materials, electrons belong either to the conduction band, where they are free to move throughout the material, or the valence band, where they remain tightly bound to the atoms. These two bands are separated by a bandgap, which is a region where no electronic states exist due to the quantized nature of energy levels. The basic idea behind the multi-bandgap sensor is to exploit the filtering behavior of semiconductor absorption due to their bandgaps. Most semiconductors will transmit nearly all of the light with an energy less than the bandgap energy of the semiconductor, while concomitantly absorbing nearly all of the light above the bandgap energy. As such, when higher bandgap materials are stacked on top of lower bandgap materials, a series of bandpass filters can be constructed using the different layers. For each layer, the absorbed photons will induce a photoelectric effect and the resulting electric currents can be read out. Photons with an energy less than the bandgap energy of that layer will be transmitted to the layer below.

Multijunction solar cells use filtering of semiconductors to maximize absorption of the sun's spectrum. For a solar cell, whenever a photon is absorbed, most all of the energy in that photon in excess of the band gap energy ends up being lost. Producing a useful solar cell is thus an optimization problem of the bandgap—a lower bandgap means more photons are absorbed (as additional lower energy photons can now be absorbed), but that comes with the cost of being able to extract less energy from them (because there is less energy from each photon even though more of them are absorbed).

Multi-junction solar cells get around this limitation by using multiple layers of semiconductors. The higher layers absorb a larger energy from the higher-energy photons, and the lower layers absorb the photons that were too low-energy to be absorbed in the higher layers, extracting the more limited energy from them while not wasting the extra energy stored in the already-absorbed, higher-energy photons.

Chu-En Chang, et al., “Multiband Charge-Coupled Device,” 2012 IEEE Nuclear Science Symposium and Medical Imaging Conference Record (NSS/MIC), Oct. 27, 2012 (“Chang”) proposes a multi-band CCD focused on the visible portion of the electromagnetic spectrum. However, Chang does not use different semiconducting materials with different bandgaps to mimic the filtering behavior of light. Instead, Chang uses stacked layers of silicon with varying thicknesses to achieve a result over a narrower region of the spectrum.

The Sigma Foveon X3 Quattro is a CMOS sensor that utilizes different absorption depths of different frequencies of light in different depths of silicon to perform filtering. The Foveon X3 Quattro is limited to only visible light and has broadly overlapping absorption for the red, green, and blue sub-pixels that render it of limited use for astronomy imaging. Overlapping absorption bands negatively affect the spectroscopic and photometric performance of an instrument since the wavelength of light from an astronomical source cannot be well constrained without distinct absorption bands. Focal plane array detectors have a similar objective, but image in the mid-IR to far-IR region. Some multi-bandgap solutions us dichroic filters and multiple camera sensors, but apply different principles entirely.

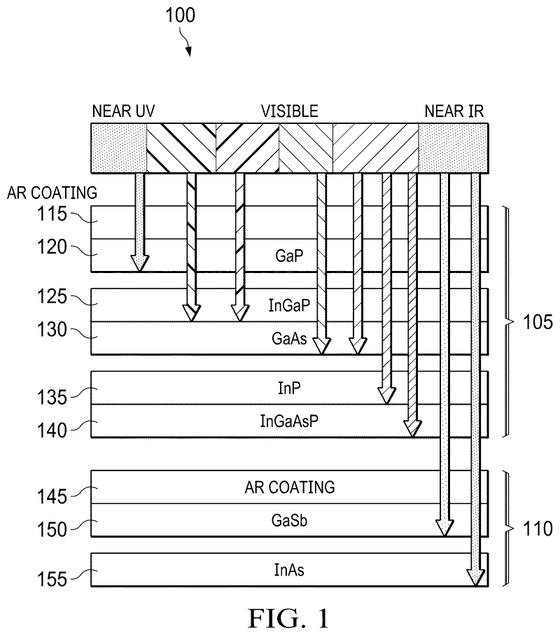

FIG. 1 is a schematic diagram of a CCD 100. The CCD 100 comprises a primary device 105 and a secondary device 110. The primary device 105 captures visible light and near-IR light with wavelengths in the about 300-1,000 nm range and may therefore be referred to as a visible detector. The secondary device 110 captures near-IR light with wavelengths in the about 1,000-2,000 nm range and may therefore be referred to as an IR detector. Thus, the CCD 100 captures light with wavelengths in the about 300-2,000 nm range. The primary device 105 and the secondary device 110 comprise multiple stacked layers as described below. The layers that comprise semiconductor materials are of different materials that absorb and transmit different wavelength bands, so they may be referred to as filters and the CCD 100 may be referred to as a multi-bandgap CCD.

The primary device 105 comprises an (optional) upper AR coating layer 115, a GaP layer 120, an InGaP layer 125, a GaAs layer 130, an InP layer 135, and an InGaAsP layer 140. The optional upper AR coating layer 115 reduces reflection to maximize the amount of light that enters the GaP layer 120, the GaP layer 120 absorbs purple and surrounding light and transmits light of longer wavelengths, the InGaP layer 125 absorbs blue through yellow light and transmits light of longer wavelengths, the GaAs layer 130 absorbs orange and red light and transmits light of longer wavelengths, the InP layer 135 absorbs near-IR light just beyond the visible spectrum and surrounding light and transmits light of longer wavelengths, and the InGaAsP layer 140 absorbs light slightly further into the near-IR and surrounding light and transmits light of longer wavelengths. The composition of the InGaP layer 125 is lattice matched to the composition of the GaAs layer 130, and the composition of the InGaAsP layer 140 is lattice matched to the InP layer 135.

The secondary device 110 comprises an (optional) lower AR coating layer 145, a GaSb layer 150, and an InAs layer 155. The optional lower AR coating layer 145 reduces reflection to maximize the amount of light that enters the GaSb layer 150, the GaSb layer 150 absorbs near-IR light with wavelengths 1000 and 1700 nm range and transmits light of longer wavelengths, and the InAs layer 155 absorbs near-IR light with wavelengths in the about 1700-1900 nm range.

The optional upper and lower AR coating layers 115 and 145 help prevent or substantially reduce reflections at and near a chosen wavelength. Their thicknesses may be chosen to ensure near-constant absorption across each layer instead of higher transmission in only one region of the spectrum. The optional upper AR coating layer 115 may comprise a sub-layer of MgF₂ and a sub-layer of CeF₃, each of which may be about 100 nm thick. The optional lower AR coating layer 145 may comprise a layer of SiO₂, which may be about 200 nm thick.

Some AR coatings designed for the visible spectrum, and thus appropriate for the primary device 105, reflect light in the IR spectrum intended for the secondary device 110. In other words, it may be difficult to design or obtain a single AR coating that can focus absorption across the entire 300-2,000 nm range. Having an upper and a lower AR coating layer 115 and 145 addresses that issue. In addition, the inclusion of both the upper and lower AR coating layers 115, 145 improves light absorption by as much as 30%.

Beyond the standard AR monolayer and bilayer coatings discussed above, other designs are possible. In a first example, GRIN coatings use smoothly-changing refractive indices to produce broadband AR coverage. In a second example, nano-structure coatings have structures smaller than the wavelength of the light to produce effective refractive indices that vary with depth, similar to the GRIN coatings. In a third example, reflectors tuned to specific bands improve the selectivity of the filters by reflecting the higher-energy photons back into the higher layers rather than transmitting them to the lower layers, while still transmitting the lower-energy photons to the lower layers. In a fourth example, DBRs behave similar to those reflectors and have specific stop-bands at which they reflect and transmit most of the rest of the light.

The layers of the CCD 100 are bonded together with epoxy or another material, which contrasts with the successive growth pattern of monolithic solar cell devices. The white gaps in FIG. 1 may represent additional AR coating layers or other optical management layers that avoid lattice mismatches, while allowing for the desired absorption and transmission of light in the semiconductor layers. The relatively larger white gap between the primary device 105 and the secondary device 110 may indicate a relatively thicker AR coating layer, and there may be another AR coating layer at the bottom of the primary device 105. The semiconductor layers may have substantially non-overlapping bandwidths. While the semiconductor layers are shown as comprising specific materials, they may comprise other materials that absorb and transmit light as desired. Those materials may be in fewer or more layers based on efficiency, cost, or other considerations. While the primary device 105 and the secondary device 110 are shown as two separate devices for illustration, they can be a single device or two separate devices. In the latter case, they can be vertically arrayed as shown or horizontally arrayed.

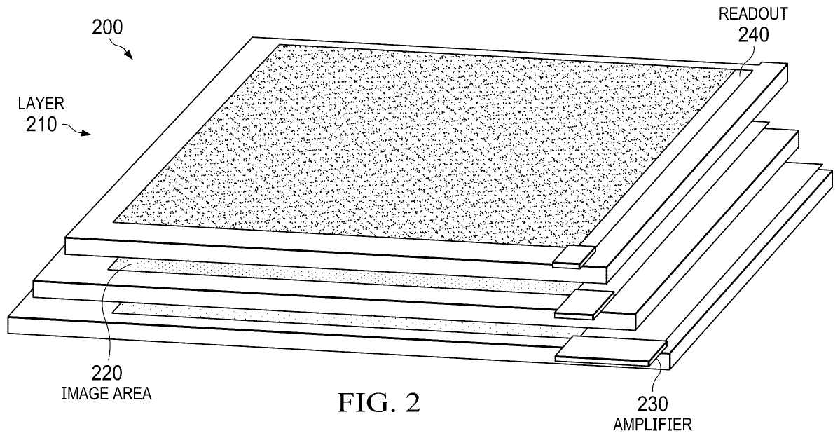

FIG. 2 is a schematic diagram of a CCD sensor 200. The CCD sensor 200 is shown as having 3 layers 210, but it may have more layers, for instance, the same number of layers as the CCD 100. Each of the layers 210 comprises an image area 220, an amplifier 230, and a readout 240. Combined, the image areas 220 form an array of CCDs 100, where each CCD 100 is associated with a single pixel. For easy access, the readouts 240 extend slightly out from the layer 210 above their respective layers 210. The amplifiers 230 and the readouts 240 are placed along the perimeter of the CCD sensor 200 so that they do not interfere with lower-energy light that passes to the lower layers 210.

In operation, light enters the CCD sensor 200 from the top and absorbs in each of the layers 210, the image areas 220 convert the light into electrical signals, the readouts 240 convert the electrical signals into a combined electrical signal, and the amplifiers 230 amplify the combined electrical signals. A computer (not shown) analyzes the combined electrical signals in each layer 210, associates the combined electrical signals into pixels based on intensities of the combined electrical signals, and creates an image by combining the pixels. A memory may store the image, and a display may display the image.

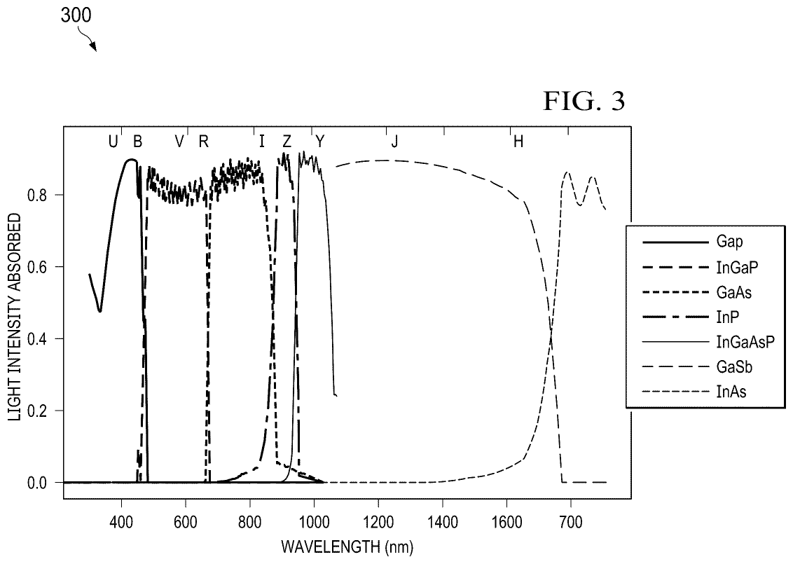

FIG. 3 is a graph 300 of light intensity absorbed as a function of wavelength for the CCD 100 in FIG. 1. The x-axis of the graph 300 is wavelength in nm, and the y-axis of the graph is normalized light intensity absorbed. The graph 300 demonstrates efficiency of the CCD 100. At the top of the graph 300, the astronomy photometric letters of U, B, V, R, I, Z, Y, J, and H are shown above their corresponding bands. There is a consistent, high efficiency across the majority of the graph 300 spectrum. The first five materials that span bands U-Y are in the primary device 105, while the remaining two materials are in the secondary device 110.

As shown in FIG. 3, based on the measured areas under the absorption curves, the layer of gallium phosphide (GaP) has a light selectivity of at least 95% in a range of wavelengths between 300 nm and 465 nm, the layer of indium gallium phosphide (InGaP), positioned below the layer of GaP, has a light selectivity of at least 95% in a range of wavelengths between 465 nm and 670 nm, the layer of gallium arsenide (GaAs), positioned below the layer of InGaP has a light selectivity at least 89% in a range of wavelengths between 670 nm and 875 nm, the layer of indium phosphide (InP), positioned below the layer of GaAs, has a light selectivity at least 86% in a range of wavelengths between 875 nm and 945 nm, the layer of indium gallium arsenide phosphide (InGaAsP), positioned below the layer of GaAs has a light selectivity of at least 89% in a range of wavelengths between 945 nm and 1070 nm, the layer of gallium antimonide (GaSb), positioned below the layer of InGaAsP has a light selectivity of at least 95% in a range of wavelengths between 1070 nm and 1740 nm, and the layer of indium arsenide (InAs), positioned below the layer of GaSb, has a light selectivity of at least 92% in a range of wavelengths between 1740 nm and 1900 nm.

To explore the wavelength-dependent transmission for various possible materials, several transfer matrix simulations were preformed using Matlab code. The sensor is modeled as a series of stacked materials of varying thicknesses with a broadband (wavelength λ=300-2000 nm) spectrum incident perpendicular to the surface. With this method, the light passing in each direction through the layers is described as 2-vector (one wave going up and one wave going down). The reflection and transmission at each boundary between layers, as well as the propagation through each layer, was calculated using 2×2 matrices.

Taking the matrix product of the whole system allows one to model the behavior of the whole device. To generate these matrices, the extinction coefficient and the refractive index of each layer (i.e., the complex refractive index) as a function of wavelength, as well as the thickness of each layer, was input. Available measurements of the real and complex refractive indices for all materials were used as the input to the transfer matrix program. These results were transformed into an equivalent light absorption calculation to obtain the graph 300.

It is important to compare the theoretical performance of these devices to existing filter systems. The two most significant metrics of the performance of the CCD 100 are the amount of light absorbed and the amount lost due to reflection at each interface where two layers meet. Standard photometric filters have transmission approaching 99% near their central wavelength. As evident from the graph 300, the absorption at each layer is on the order of 80-85%. Although this is not on par with existing filters, it is important to consider that the optical device is capable of simultaneously imaging across several bands at once. Thus, any additional exposure time required to match the sensitivity of existing photometric filters will be greatly offset by the time saved by not having to repeat observations in different bands. In addition, the performance is comparable to existing sensors, which generally have an absorption of 80-85%.

It is also important to replicate the selectivity in each band of existing photometric filter systems. Astronomical sources in general have complex spectra containing different spectral features. Different spectral features emit more strongly in different regions of the electromagnetic spectrum. Astronomers usually select a particular band that they expect the spectral feature to be most visible in. In other cases, a spectral feature may be completely invisible in one band but appear in another. For this reason, it is essential that any broadband detector has not only the ability to record the flux of incident light, but also the ability to identify which regions of the electromagnetic spectrum the flux comes from.

The CCD 100 replicates this behavior by exploiting the bandgaps of the different stacked materials. Even though the device will image a large portion of the electromagnetic spectrum at once, each layer of the device will only record photons with an energy between the bandgap of the above layer and the bandgap of the layer itself. The combined efficiency of the device, or the sum of the efficiency of each layer, will be much higher than existing astronomical filters while replicating their function. Assuming a five-layer device, the combined efficiency will be 400% that of a traditional device that will have to make five separate observations with different photometric filters taking four to five times as long. That is, the CCD 100 will be significantly more efficient and require less exposure time.

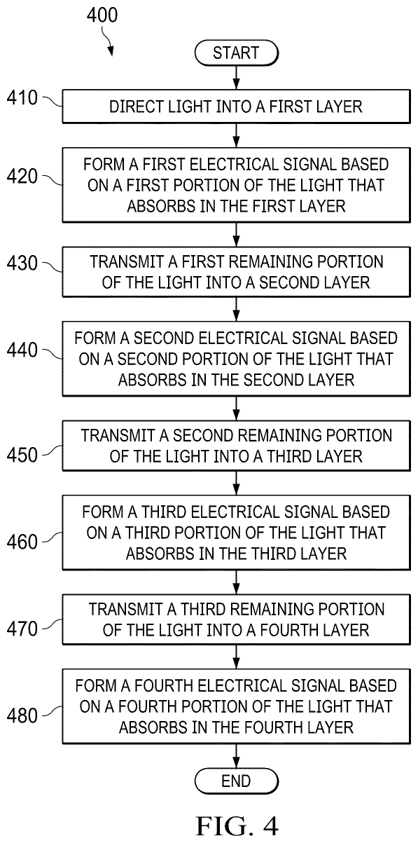

FIG. 4 is a flowchart illustrating a method 400 of performing an image observation. The CCD sensor 200 implements the method 400. At step 410, light is directed into a first layer. The first layer is in a primary device of a CCD. The first layer comprises a first semiconductor material. At step 420, a first electrical signal is formed based on a first portion of the light that absorbs in the first layer. At step 430, a first remaining portion of the light is transmitted into a second layer. The second layer is in the primary device. The second layer comprises a second semiconductor material. At step 440, a second electrical signal is formed based on a second portion of the light that absorbs in the second layer. At step 450, a second remaining portion of the light is transmitted into a third layer. The third layer is in a secondary device. The third layer comprises a third semiconductor material and may be the top semiconducting layer in the secondary device. At step 460, a third electrical signal based on a third portion of the light that absorbs in the third layer. At step 470, a third remaining portion of the light is transmitted into a fourth layer. The fourth layer is in the secondary device. The fourth layer comprises a fourth semiconductor material and may be the bottom semiconducting layer in the secondary device. Finally, at step 480, a fourth electrical signal is formed based on a fourth portion of the light that absorbs in the fourth layer.

The method 400 may implement other embodiments as well. For instance, the method 400 further comprises passing, before directing the light into the first layer, the light through a first AR coating layer. The method 400 further comprises passing, after transmitting the first remaining portion and before transmitting the second remaining portion, the second remaining portion through a second AR coating layer. The method 400 further comprises generating a pixel based on the first electrical signal, the second electrical signal, the third electrical signal, or the fourth electrical signal; and displaying the pixel. The method 400 further comprises using the pixel for astronomical imaging.

In at least certain embodiments, the present disclosure is directed to a charge-coupled device (CCD) comprising a primary device and a secondary device, wherein the primary device comprises (1) a first layer, consisting of gallium phosphide (GaP) and having a light selectivity of at least 95% in a range of wavelengths between 300 nm and 465 nm, (2) a second layer, consisting of indium gallium phosphide (InGaP), the second layer positioned below the first layer and directly connected thereto, and having a light selectivity of at least 95% in a range of wavelengths between 465 nm and 670 nm, (3) a third layer, consisting of gallium arsenide (GaAs), the third layer positioned below the second layer and directly connected and lattice-matched thereto, and having a light selectivity at least 89% in a range of wavelengths between 670 nm and 875 nm, (4) a fourth layer, consisting of indium phosphide (InP), the fourth layer positioned below the third layer and directly connected thereto, and having a light selectivity at least 86% in a range of wavelengths between 875 nm and 945 nm, (5) a fifth layer, consisting of indium gallium arsenide phosphide (InGaAsP), the fifth layer positioned below the fourth layer and directly connected and lattice matched thereto, and having a light selectivity of at least 89% in a range of wavelengths between 945 nm and 1070 nm; and the secondary device comprises (6) a sixth layer, consisting of gallium antimonide (GaSb), the sixth layer positioned below the fifth layer and directly connected thereto, and having a light selectivity of at least 95% in a range of wavelengths between 1070 nm and 1740 nm, and (7) a seventh layer, consisting of indium arsenide (InAs), the seventh layer positioned below the sixth layer and directly connected thereto, and having a light selectivity of at least 92% in a range of wavelengths between 1740 nm and 1900 nm. The CCD may comprise an upper antireflective (AR) coating layer positioned above the first layer of the primary device, wherein the upper AR coating comprises a first sub-layer, and a second sub-layer positioned between the first sub-layer and the first layer of the primary device. The first sub-layer may comprise magnesium fluoride (MgF₂) and the second sub-layer may comprise cerium fluoride (CeF₃). The CCD may comprise one or more intermediate AR coating layers positioned within the primary device, for example between the first and second layers, the second and third layers, the third and fourth layers, and/or the fourth and fifth layers. The intermediate AR coating layer may comprise a first sub-layer comprising a first sub-material and a second sub-layer comprising a second sub-material. The CCD may comprise a lower AR coating layer positioned between the primary device and the secondary device. The lower AR coating layer may comprise silicon dioxide (SiO₂). The CCD may further comprise at least one of a gradient-index (GRIN) coating layer, a nano-structure coating layer, a reflector tuned to a band, and a distributed Bragg reflector (DBR). The at least one GRIN coating layer, nano-structure coating layer, reflector tuned to a band, and DBR may be positioned above the first layer of the primary device. The at least one GRIN coating layer, nano-structure coating layer, reflector tuned to a band, and DBR may be positioned between the primary device and the secondary device. The CCD may be configured to be used as a camera. The CCD may be configured to be used for astronomical imaging. The CCD of any of the above embodiments may be used in an imaging method comprising the steps of directing light into the CCD, recording electrical signals generated from the primary device and the secondary device, generating pixels based on the electrical signals, and displaying the pixels. The displayed pixels may be used for astronomical imaging.

While the present disclosure has been described in connection with certain embodiments so that aspects thereof may be more fully understood and appreciated, it is not intended that the present disclosure be limited to these particular embodiments. On the contrary, it is intended that all alternatives, modifications and equivalents are included within the scope of the present disclosure. Thus the examples described above, which include particular embodiments, will serve to illustrate the practice of the present disclosure, it being understood that the particulars shown are by way of example and for purposes of illustrative discussion of particular embodiments only and are presented in the cause of providing what is believed to be the most useful and readily understood description of procedures as well as of the principles and conceptual aspects of the presently disclosed methods and compositions. Changes may be made in the structures of the various components described herein, or the methods described herein without departing from the spirit and scope of the present disclosure.

What is claimed is:

1. A charge-coupled device (CCD) comprising:
a primary device comprising:
a first layer, consisting of gallium phosphide (GaP) and having a light selectivity of at least 95% in a range of wavelengths between 300 nanometers (nm) and 465 nm;
a second layer, consisting of indium gallium phosphide (InGaP), the second layer positioned below the first layer and directly connected thereto, and the second layer having a light selectivity of at least 95% in a range of wavelengths between 465 nm and 670 nm;
a third layer, consisting of gallium arsenide (GaAs), the third layer positioned below the second layer and directly connected and lattice-matched thereto, and the third layer having a light selectivity of at least 89% in a range of wavelengths between 670 nm and 875 nm;
a fourth layer, consisting of indium phosphide (InP), the fourth layer positioned below the third layer and directly connected thereto, and the fourth layer having a light selectivity of at least 86% in a range of wavelengths between 875 nm and 945 nm;
a fifth layer, consisting of indium gallium arsenide phosphide (InGaAsP), the fifth layer positioned below the fourth layer and directly connected and lattice matched thereto, and the fifth layer having a light selectivity of at least 89% in a range of wavelengths between 945 nm and 1070 nm; and
a secondary device comprising:
a sixth layer, consisting of gallium antimonide (GaSb), the sixth layer positioned below the fifth layer and directly connected thereto, and the sixth layer having a light selectivity of at least 95% in a range of wavelengths between 1070 nm and 1740 nm; and
a seventh layer, consisting of indium arsenide (InAs), the seventh layer positioned below the sixth layer and directly connected thereto, and the seventh layer having a light selectivity of at least 92% in a range of wavelengths between 1740 nm and 1900 nm.

2. The CCD of claim 1, further comprising an upper antireflective (AR) coating layer positioned above the first layer and comprising:
a first sub-layer, and
a second sub-layer positioned between the first sub-layer and the first layer.

3. The CCD of claim 2, wherein the first sub-layer comprises magnesium fluoride (MgF₂) and the second sub-layer comprises cerium fluoride (CeF₃).

4. The CCD of claim 2, further comprising an intermediate AR coating layer positioned between the first layer and the second layer, the second layer and the third layer, the third layer and the fourth layer, and/or the fourth layer and the fifth layer.

5. The CCD of claim 4, wherein the intermediate AR coating layer comprises:
a third sub-layer comprising a first sub-material; and
a fourth sub-layer comprising a second sub-material.

6. The CCD of claim 1, further comprising a lower antireflective (AR) coating layer positioned between the primary device and the secondary device.

7. The CCD of claim 6, wherein the lower AR coating layer comprises silicon dioxide (SiO₂)

8. The CCD of claim 1, further comprising at least one of a gradient-index (GRIN) coating layer, a nano-structure coating layer, a reflector tuned to a band, or a distributed Bragg reflector (DBR).

9. The CCD of claim 8, wherein the at least one of the GRIN coating layer, the nano-structure coating layer, the reflector tuned to a band, or the DBR is positioned above the first layer.

10. The CCD of claim 8, wherein the at least one of the GRIN coating layer, the nano-structure coating layer, the reflector tuned to a band, or the DBR is positioned between the primary device and the secondary device.

11. The CCD of claim 1, wherein the CCD is configured to be used as a camera.

12. The CCD of claim 1, wherein the CCD is configured to be used for astronomical imaging.

13. An imaging method, comprising:
providing a charge-coupled device (CCD) comprising:
a primary device comprising:
a first layer, consisting of gallium phosphide (GaP) and having a light selectivity of at least 95% in a range of wavelengths between 300 nanometers (nm) and 465 nm,
a second layer, consisting of indium gallium phosphide (InGaP), the second layer positioned below the first layer and directly connected thereto, and the second layer having a light selectivity of at least 95% in a range of wavelengths between 465 nm and 670 nm,
a third layer, consisting of gallium arsenide (GaAs), the third layer positioned below the second layer and directly connected and lattice-matched thereto, and the third layer having a light selectivity of at least 89% in a range of wavelengths between 670 nm and 875 nm,
a fourth layer, consisting of indium phosphide (InP), the fourth layer positioned below the third layer and directly connected thereto, and the fourth layer having a light selectivity of at least 86% in a range of wavelengths between 875 nm and 945 nm,
a fifth layer, consisting of indium gallium arsenide phosphide (InGaAsP), the fifth layer positioned below the fourth layer and directly connected and lattice matched thereto, and the fifth layer having a light selectivity of at least 89% in a range of wavelengths between 945 nm and 1070 nm; and
a secondary device comprising:
a sixth layer, consisting of gallium antimonide (GaSb), the sixth layer positioned below the fifth layer and directly connected thereto, and the sixth layer having a light selectivity of at least 95% in a range of wavelengths between 1070 nm and 1740 nm, and
a seventh layer, consisting of indium arsenide (InAs), the seventh layer positioned below the sixth layer and directly connected thereto, and the seventh layer having a light selectivity of at least 92% in a range of wavelengths between 1740 nm and 1900 nm;
directing light into the CCD;
recording electrical signals generated from the primary device and the secondary device based on the light;
generating pixels based on the electrical signals; and
displaying the pixels as displayed pixels.

14. The method of claim 13, further comprising using the displayed pixels for astronomical imaging.
